(19) United States
(12) Patent Application Publication
(10) Pub. No.: US 2023/0189473 A1
(43) Pub. Date: Jun. 15, 2023

(54) COOLING DEVICE AND PROJECTION IMAGE DISPLAY DEVICE PROVIDED WITH SAME

(71) Applicant: Panasonic Intellectual Property Management Co., Ltd., Osaka (JP)

(72) Inventors: Hiroyuki TERAWAKI, Osaka (JP); Manabu CHIKAYAMA, Osaka (JP)

(21) Appl. No.: 18/107,824

(22) Filed: Feb. 9, 2023

Related U.S. Application Data
(63) Continuation of application No. PCT/JP2021/026853, filed on Jul. 16, 2021.

(30) Foreign Application Priority Data
Aug. 20, 2020 (JP) 2020-139424

(51) Int. Cl. H05K 7/20; G03B 21/16; F21V 29/60

(52) U.S. Cl. CPC H05K 7/20154; H05K 7/20418; G03B 21/16; F21V 29/60

(57) ABSTRACT

Provided is a cooling device including: a container that is sealed and accommodates a first heating element; a first radiator disposed outside the container; a first air blower that blows wind to the first radiator; and a heat dissipator that is disposed outside the container to receive the wind from the first air blower and dissipates heat of the first heating element.

### TECHNICAL FIELD

The present disclosure relates to a cooling device and a projection image display device including the cooling device.

### BACKGROUND ART

A projection image display device such as a projector may be deteriorated in luminance by dust and dirt that enter the inside of the device and adhere to a prism and an image display. To avoid this state, demand for housing the prism and the image display in a sealed container has increased.

However, when the prism and the image display are accommodated in a sealed container, the container reaches a high temperature due to heat generated during operation. Thus, to prevent the image display of the projection image display device from reaching a high temperature, a cooling device is required to cool the image display accommodated in the container, and air and other members in the sealed container.

For example, PTL 1 discloses a configuration in which a heat sink of each of a plurality of display devices is exposed to the outside of a dustproof container. A fan for cooling the heat sink exposed to the outside is individually provided. Additionally, a heat exchange unit different from the heat sink and the fan for cooling the display device is provided to cool air and a prism in the dustproof container. Such a configuration achieves both sealing of the dustproof container and cooling of the display device in the dustproof container.

### CITATION LIST

### Patent Literature

PTL 1: Unexamined Japanese Patent Publication No. 2016-133609

### SUMMARY OF THE INVENTION

However, the cooling device is enlarged as a whole because coolers for cooling members accommodated in the container are individually installed.

It is an object of the present disclosure to provide a cooling device capable of saving a space and a projection image display device including the cooling device.

A cooling device of the present disclosure includes: a container that is sealed and accommodates a first heating element; a first radiator disposed outside the container; a first air blower that blows wind to the first radiator; and a heat dissipator that is disposed outside the container to receive the wind from the first air blower and dissipates heat of the first heating element.

A projection image display device of the present disclosure includes the cooling device, the first heating element, the second heating element, and a prism that is accommodated in a container to separate incident light into a plurality of colors of light and combine the plurality of colors of light. The second heating element includes an image display facing one surface of the prism, and the first heating element includes a light shielding plate that shields light reflected from the image display.

The cooling device of the present disclosure enables providing a cooling device capable of saving a space and a projection image display device including the cooling device.

### BRIEF DESCRIPTION OF THE DRAWINGS

FIG. 1 is an external perspective view of a cooling device according to a first exemplary embodiment.

FIG. 2 is a plan view of the cooling device according to the first exemplary embodiment.

FIG. 3 is a plan view of the cooling device according to the first exemplary embodiment from which a lid is removed.

FIG. 4 is a perspective view of the cooling device according to the first exemplary embodiment in a state where a container is not illustrated.

FIG. 5 is a perspective view of the cooling device according to the first exemplary embodiment in a state where the container is not illustrated.

FIG. 6 is a perspective view of the cooling device according to the first exemplary embodiment in a state where a container and a blower are not illustrated.

FIG. 7 is a configuration diagram of a projection image display device according to a second exemplary embodiment.

### DESCRIPTION OF EMBODIMENT

Hereinafter, exemplary embodiments will be described in detail with reference to the drawings as appropriate. However, unnecessarily detailed description may not be described. For example, the detailed description of already well-known matters and the overlap description of substantially the same configurations may not be described. This is to avoid unnecessary redundancy in the following description and to facilitate understanding by those skilled in the art.

The inventor(s) provides the accompanying drawings and the following description for those skilled in the art to fully understand the present disclosure, and does not intend to limit the subject matter described in the scope of claims.

### First Exemplary Embodiment

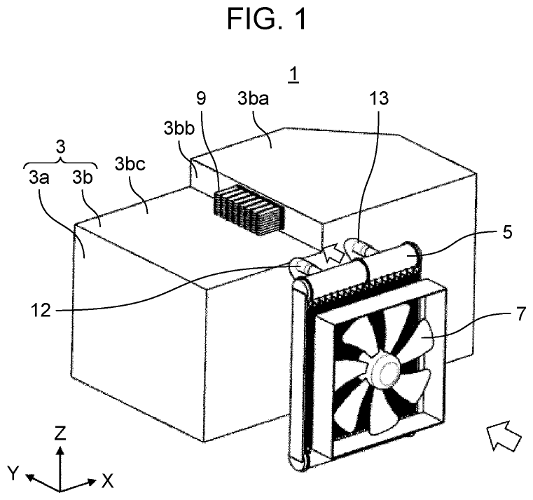

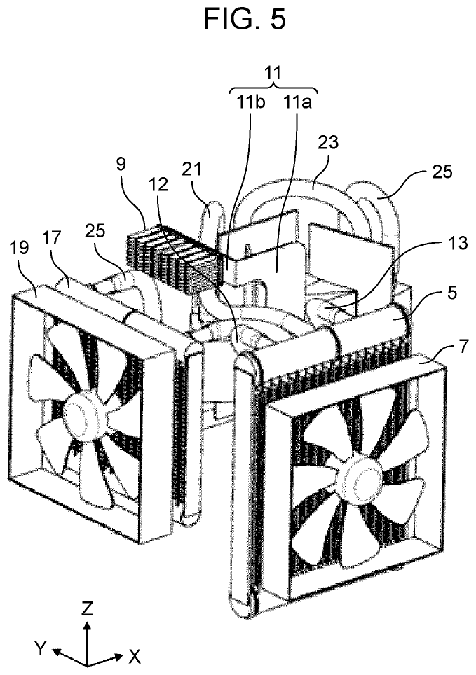

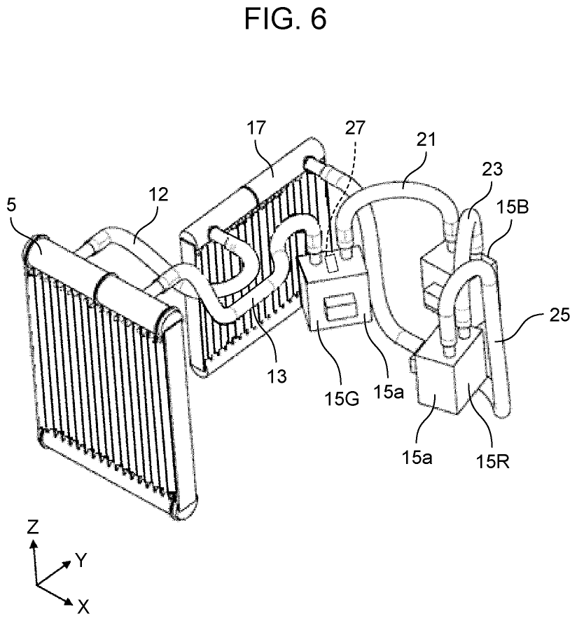

A first exemplary embodiment will be described below with reference to FIGS. 1 to 6.

[1-1. Configuration]

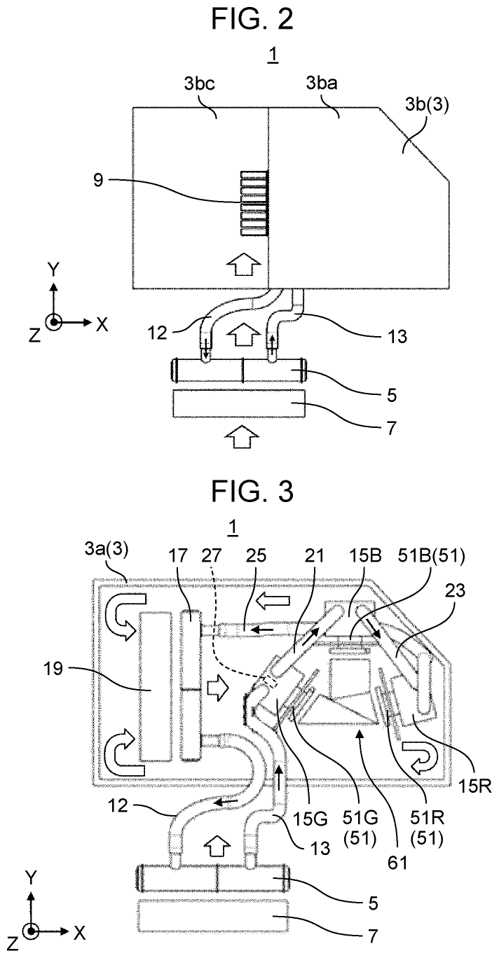

A schematic configuration of cooling device 1 according to the first exemplary embodiment of the present disclosure will be described with reference to FIGS. 1 and 2. FIG. 1 is an external perspective view of cooling device 1 according to the first exemplary embodiment of the present disclosure. FIG. 2 is a plan view of the cooling device according to the first exemplary embodiment. For convenience of the following description, an XYZ orthogonal coordinate system shown in the drawings is used in each drawing, and a Z-axis direction is defined as an up-down direction.

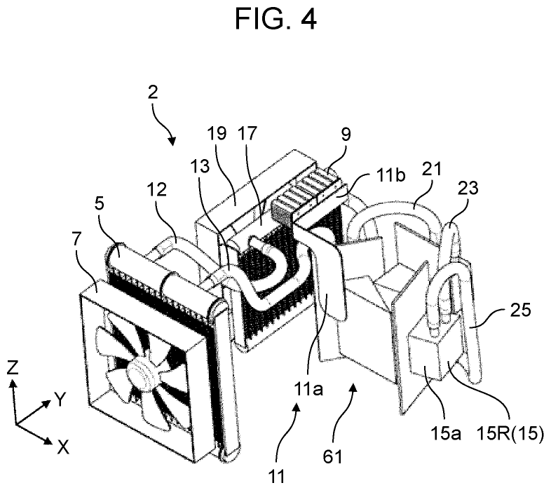

Cooling device 1 includes container 3, first radiator 5, first air blower 7, and heat dissipator 9. Container 3 accommodates light shielding plate 11 (see FIG. 4) as a first heat generator. Container 3 includes body 3a and lid 3b. Lid 3b is fixed to body 3a with a sealant such as an O-ring interposed therebetween, for example, and container 3 is sealed. Thus, dust and dirt can be prevented from entering container 3 from the outside. Lid 3b includes first upper surface 3ba, side surface 3bb, and second upper surface 3bc. Side surface 3bb extends downward from one side of first upper surface 3ba, and second upper surface 3bc extends parallel to first upper surface 3ba from a lower side of side surface 3bb. Heat dissipator 9 is attached to side surface 3bb and is connected to light shielding plate 11 in container 3 with a wall interposed between heat dissipator 9 and light shielding plate 11. Heat dissipator 9 includes a heat dissipation fin made of metal, for example. A connection surface between heat dissipator 9 and side surface 3bb is sealed with grease, for example.

First radiator 5 is disposed outside container 3. First radiator 5 is connected to pipe 12 through which a refrigerant flowing from the inside of container 3 passes and pipe 13 through which the refrigerant flowing to the inside of container 3 passes. Pipe 12, 13 is inserted into a through-hole (not illustrated) provided in container 3, and a part where pipe 12, 13 is inserted into the through-holes is sealed with a cushion or the like.

Refer to FIG. 3. FIG. 3 is a plan view of cooling device 1 according to the first exemplary embodiment from which lid 3b is removed. Container 3 accommodates image display 51 as a second heat generator and prism unit 61. Cooling device 1 further includes heat receiver 15 that receives driving heat of image display 51. The first exemplary embodiment includes three image displays 51G, 51B, 51R that are accommodated in container 3. Heat receiver 15 includes first heat receiving element 15G, second heat receiving element 15B, and third heat receiving element 15R that respectively absorb driving heat of image displays 51G, 51B, 51R.

Image display 51 includes three types of image display corresponding to three colored light beams separated by prism unit 61, such as image display 51B for blue light modulation, image display 51R for red light modulation, and image display 51G for green light modulation. Image displays 51B, 51R, 51G are accommodated in container 3. When image displays 51B, 51R, 51G are collectively referred to, they are simply referred to as image display 51.

Cooling device 1 further includes second radiator 17, second air blower 19, and pipes 21, 23, 25. Heat receiver 15 incorporates pump 27, and pump 27 can feed a refrigerant to a pipe. Pipe 21 connects first heat receiving element 15G and second heat receiving element 15B. Pipe 23 connects second heat receiving element 15B and third heat receiving element 15R. Pipe 25 connects third heat receiving element 15R and second radiator 17. Pipe 13 connects first radiator 5 and first heat receiving element 15G, and pipe 12 connects second radiator 17 and first radiator 5. First radiator 5, first air blower 7, heat receiver 15, pipes 12, 13, 21, 23, second radiator 17, second air blower 19, and pump 27 constitute liquid-cooling system 2. First air blower 7 and second air blower 19 are each a fan, for example.

Pump 27 causes the refrigerant cooled by first radiator 5 to sequentially flow through pipe 13, first heat receiving element 15G, pipe 21, second heat receiving element 15B, pipe 23, third heat receiving element 15R, pipe 25, second radiator 17, and pipe 12, and return to first radiator 5 for circulation.

Each of first to third heat receiving elements 15G, 15B, 15R includes a metal fin (not illustrated) connected to a back surface of image display 51, and case 15a that accommodates the metal fin, for example. Allowing the refrigerant to flow into case 15a enables heat of the metal fin to be absorbed by the refrigerant. Additionally, flow paths of the refrigerant to first to third heat receiving elements 15G, 15B, 15R are connected in series by pipes 13, 21, 23, 25, so that routing of the pipes can be simplified.

The refrigerant gradually raised in temperature by first to third heat receiving elements 15G, 15B, 15R flows to second radiator 17. Container 3 contains second radiator 17 that is disposed among second air blower 19, image display 51, and prism unit 61.

Cooling air flowing from second air blower 19 through second radiator 17 cools image display 51 and prism unit 61. The cooling air having increased in temperature due to image display 51 and prism unit 61 circulates in container 3 and is fed again from second air blower 19 to second radiator 17. The second radiator absorbs heat of the cooling air raised in temperature by the refrigerant to lower the temperature of the cooling air. The cooled cooling air flows again from the second radiator into container 3. In this manner, the inside of container 3 is cooled.

The refrigerant having further raised in temperature due to second radiator 17 flows through pipe 12 and is cooled by first radiator 5 disposed outside container 3. The refrigerant is lowered in temperature in first radiator 5 using cooling wind fed from first air blower 7. The wind having cooled first radiator 5 flows directly toward heat dissipator 9.

Image display 51 includes a reflective image display element, for example. The reflective image display element is a digital mirror device (DMD). The reflective image display element includes a plurality of minute mirrors that are two-dimensionally disposed. Inclination directions of the respective minute mirrors are controlled in two directions in accordance with an image signal from the outside. Reflected light from the mirror at a tilt angle at the time of an ON signal returns to prism unit 61 at an incident angle of 0 degree, and is incident on prism unit 61 again at a large angle at the time of an OFF signal. The light incident on prism unit 61 at the time of the OFF signal is emitted from an upper part of prism unit 61, and is emitted to light shielding plate 11 (see FIG. 4). As a result, temperature of light shielding plate 11 increases.

Light shielding plate 11 includes photo detector 11a irradiated with the light emitted from prism unit 61 and heat-conducting plate 11b extending from an upper part of photo detector 11a. Heat dissipator 9 is connected to heat-conducting plate 11b via container 3, and heat of photo detector 11a is transferred to heat dissipator 9 via heat conducting plate 11b and container 3 as heat conductive members. That is, the heat of photo detector 11a is directly conducted to heat dissipator 9 and dissipated without using the refrigerant. Although heat-conducting plate 11b and photo detector 11a are integrally formed, they may be separately formed. Heat-conducting plate 11b is made of metal having high thermal conductivity, such as copper or a graphite sheet.

First radiator 5 is disposed between first air blower 7 and heat dissipator 9. Thus, heat dissipator 9 is cooled by wind having flowed out of first air blower 7 and having cooled first radiator 5. The wind having passed through first radiator 5 has a lower temperature than heat dissipator 9, so that heat dissipator 9 can be cooled. Even when the refrigerant flowing into first radiator 5 has a lower temperature than heat dissipator 9, the wind raised in temperature due to first radiator 5 has a lower temperature than heat dissipator 9, and thus heat dissipator 9 can be cooled.

[1-2. Effects and Others]

As described above, cooling device 1 according to the present exemplary embodiment includes container 3 that is sealed and accommodates light shielding plate 11 as a first heating element, first radiator 5 disposed outside container 3, first air blower 7 that feed air to first radiator 5, and heat dissipator 9 that is disposed to receive a flow of the air from first air blower 7 and dissipate heat of light shielding plate 11.

Dissipating heat of the first heating element outside container 3 and cooling heat dissipator 9 using the wind for cooling first radiator 5 enables achieving space saving of cooling device 1 for cooling light shielding plate 11 accommodated in the sealed container.

Although wind from first air blower 7 disposed opposite to first radiator 5 that cools the refrigerant flowing inside container 3 to which heat dissipator 9 is attached is used as wind to be fed to heat dissipator 9 in the first exemplary embodiment, the present disclosure is not limited to this. Wind for cooling a radiator different from first radiator 5 for cooling the refrigerant flowing from the inside of container 3 may be blown to heat dissipator 9. Alternatively, wind from an air blower attached to another container 3 or the device to cool a device different from the radiator may be blown to heat dissipator 9.

Cooling device 1 includes heat receiver 15 that receives heat of image display 51 as a second heating element disposed in container 3, pipe 13 as a first flow path through which a refrigerant cooled by first radiator 5 flows to heat receiver 15, and pipes 21, 23, 25, 12 as a second flow path through which the refrigerant raised in temperature by heat receiver 15 flows to first radiator 5.

Cooling two heating elements of light shielding plate 11 and image display 51 accommodated in sealed container 3 with one cooling device 1 enables suppressing increase in size of a cooling system.

Heat dissipator 9 is disposed to receive wind having passed through first radiator 5. Heat dissipator 9 is hotter than the refrigerant flowing through first radiator 5, so that cooling efficiency can be improved by blowing wind from first air blower 7 to heat dissipator 9 after blowing the wind to first radiator 5.

Cooling device 1 includes second air blower 19 that is accommodated in container 3 and blows wind in container 3. Second air blower 19 blows wind in container 3, so that each component in container 3, such as prism unit 61, can be cooled. Temperature in container 3 is dissipated to external air through a wall of container 3.

Cooling device 1 also includes second radiator 17 that is accommodated in container 3 and exchanges heat with air in container 3. Second air blower 19 blows wind to second radiator 17, and pipe 25 and pipe 12 in the middle of the second flow path are connected to second radiator 17. Through pipes 21, 23, 25 (an example of a third flow path), the refrigerant raised in temperature by heat receiver 15 flows to second radiator 17. Through pipe 12 (an example of a fourth flow path), the refrigerant further raised in temperature by second radiator 17 flows to the first radiator.

Second radiator 17 can absorb heat from the wind blown from second air blower 19, so that the inside of container 3 can be further cooled. Additionally, the cooling system can be prevented from further increasing in size by using one cooling device 1 to cool not only the two heating elements accommodated in sealed container 3 but also air in container 3.

Heat dissipator 9 includes a metal fin connected to light shielding plate 11. As a result, the metal fin receives a flow of air from first air blower 7, so that heat of light shielding plate 11 can be efficiently dissipated.

### Second Exemplary Embodiment

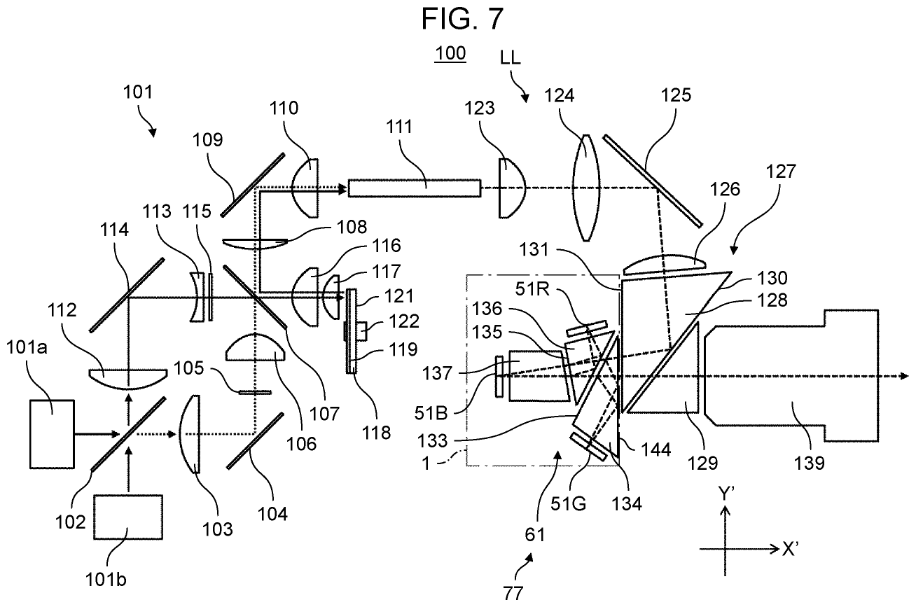

A second exemplary embodiment describes projection image display device 100 including cooling device 1 according to the first exemplary embodiment with reference to FIG. 7.

Projection image display device 100 includes light source unit 101, light guide optical system LL, modulator 77, and projection lens unit 139. Modulator 77 is accommodated in cooling device 1 of the first exemplary embodiment.

Projection image display device 100 includes light source unit 101, light guide optical system LL, prism unit 61, image display 51, cooling device 1, and projection lens unit 139. Light source unit 101 emits light, and light guide optical system LL guides the light from light source unit 101 to image display 51 via prism unit 61. Prism unit 61 separates light from light source unit 101 into blue light, red light, and green light, and guides the light to image display 51. Image display 51 modulates each separated colored light from light source unit 101 in response to an external signal. Cooling device 1 cools each image display 51. Projection lens unit 139 enlarges and projects an image generated by image light modulated by each image display 51.

Light source unit 101 includes laser diode units 101a, 101b, mirror 102, 104, 109, 114, lens 103, 108, 110, 112, 113, diffuser plate 105, 115, condenser lens 106, 116, 117, dichroic mirror 107, rod integrator 111, and phosphor wheel device 118, for example.

Each of laser diode units 101a and 101b includes a plurality of light sources. Each light source includes a pair of blue laser diodes, for example, and a collimating lens disposed on an emission side of the blue laser diodes. As a result, the light source can emit laser light with suppressed spread.

Light emitted from laser diode unit 101a is incident on mirror 102 having a partial opening. A part of the light incident on mirror 102 is emitted in a +X′-direction through the partial opening of mirror 102, and the remaining light is reflected by a reflector in a +Y′-direction.

Light emitted from laser diode unit 101b is also incident on mirror 102. When the light is incident on mirror 102, similarly, a part of the light passes through the partial opening of mirror 102 and is emitted in the +Y′-direction, and the remaining light is reflected by the reflector in the +X′-direction. The partial opening of mirror 102 has a shape that is designed to have a ratio of blue light in each of first light traveling in the +X′-direction and second light traveling in the +Y′-direction that are included in light emitted by each of laser diode units 101a and 101b, the ratio of blue light being higher in the second light.

The blue light emitted in the +X′-direction is condensed by lens 103, reflected by mirror 104, then diffused by diffuser plate 105. The diffused blue light enters condenser lens 106, becomes collimated light, and enters dichroic mirror 107 again. Dichroic mirror 107 has a characteristic of transmitting blue light and reflecting other color light. Thus, the blue light incident on dichroic mirror 107 is transmitted through dichroic mirror 107. The transmitted blue light passes through lens 108, mirror 109, and lens 110, and is condensed on an incident surface of rod integrator 111 having a rectangular opening.

The light traveling in the +Y′-direction via mirror 102 having the partial opening is converged by lens 112 and lens 113 constituting an afocal system with mirror 114 interposed therebetween and is incident on diffuser plate 115. The blue laser light incident on diffuser plate 115 is diffused here, and then passes through dichroic mirror 107 to be incident on condenser lenses 116, 117. The blue light incident thereon is incident on phosphor part 119 of phosphor wheel device 118.

Phosphor part 119 is, for example, a ceramic phosphor, and a reflection layer (not illustrated) that reflects light having a wavelength of fluorescent light is formed on a surface opposite to an incident surface of the excitation light. The reflection layer is fixed to spreader 121 having excellent thermal conductivity via an adhesive layer (not illustrated). Spreader 121 is a disk and is configured to be rotatable by motor 122 at the center.

The blue light incident on phosphor part 119 is converted into yellow light by entering phosphor part 119, reflected by reflection layer 120 on a back surface, and emitted toward condenser lens 117. The yellow light having passed through condenser lens 117 passes through condenser lens 116 and is incident on dichroic mirror 107. Here, the yellow light is reflected and condensed on the incident surface of rod integrator 111 having a rectangular opening through lens 108, mirror 109, and lens 110 similarly to the blue light. Inside rod integrator 111, the blue light of the laser light source and the yellow light of the fluorescent light are superimposed to generate white light.

As described above, light source unit 101 may have a configuration other than the above-described configuration as long as it is configured to emit white light.

Light guide optical system LL includes relay lenses 123, 124, mirror 125, field lens 126, and total reflection prism 127.

The light emitted from rod integrator 111 passes through relay lenses 123, 124 and is reflected by reflecting mirror 125. The totally reflected light passes through field lens 126 and enters total reflection prism 127. Total reflection prism 127 includes prism 128 and prism 129, and is fixed while maintaining a slight gap (air gap) between prism 128 and prism 129. The light incident on total reflection prism 127 is totally reflected by side surface 130 of prism 128, passes through side surface 131 of prism 128, and is incident on prism unit 61.

Prism unit 61 is formed by bonding and fixing first prism 134 having blue-transmitting dichroic mirror face 133 having a characteristic of reflecting blue light, second prism 136 having green-transmitting dichroic mirror face 135 having a characteristic of reflecting red light and blue light, and third prism 137. However, an air gap is provided between first prism 134 and second prism 136 to use total reflection.

Image displays 51R, 51G, 51B are disposed to face end surfaces of first prism 134, second prism 136, and third prism 137, respectively.

In each pixel of image displays 51R, 51G, 51B, the image in a white display mode returns to prism unit 61 again, passes through prisms 128, 129 of total reflection prism 127, enters projection lens unit 139, and reaches a screen not illustrated in the drawing. Thus, color display is achieved.

Projection image display device 100 of the second exemplary embodiment includes cooling device 1, first prism 134 to third prism 137 that are accommodated in container 3 and separate incident light by color separation, image displays 51G, 51B, 51R disposed facing first surfaces of first prism 134 to third prism 137, respectively, as second heating elements, and light shielding plate 11 that shields light reflected from image displays 51G, 51B, 51R, as a first heating element. Cooling device 1 includes: sealed container 3 that accommodates light shielding plate 11; first radiator 5 disposed outside container 3; first air blower 7 that blows wind to first radiator 5; and heat dissipator 9 that is disposed outside container 3 to receive a flow of the wind from first air blower 7 and dissipates heat of light shielding plate 11. Cooling device 1 further includes heat receiver 15 that receives heat of image display 51 disposed in container 3, pipe 13 through which a refrigerant cooled by first radiator 5 flows to heat receiver 15, and pipes 21, 25, 12 through which the refrigerant raised in temperature by heat receiver 15 flows to first radiator 5.

This configuration allows heat of light shielding plate 11 to be dissipated by heat dissipator 9, and heat of image display 51 to be received by heat receiver 15 cooled by the refrigerant. Only one of the two heating elements is cooled by the refrigerant, and thus the refrigerant can be prevented from excessively increasing in temperature and first radiator 5 can be prevented from enlarging. The heat dissipator of light shielding plate 11 is cooled using a cooling wind to first radiator 5 that cools the refrigerant for cooling image display 51. Thus, two coolers can be cooled by one air blower, so that space saving of cooling device 1 and projection image display device 100 can be achieved.

### Other Exemplary Embodiments

As described above, the above exemplary embodiments have been described as examples of the techniques disclosed in the present application. However, the techniques in the present disclosure are not limited to the above exemplary embodiments, and can also be applied to exemplary embodiments in which change, substitution, addition, omission, and the like are performed. Alternatively, the components described in the above exemplary embodiments may be combined to make an additional exemplary embodiment.

Although light source unit 101 in the first exemplary embodiment generates white light from a blue laser generated by laser diode unit 101a, the present disclosure is not limited thereto. White light may be generated by synthesizing light beams of respective colors from a red semiconductor laser, a blue semiconductor laser, and a green semiconductor laser, or a light source other than the laser such as a lamp may be used.

Although container 3 in the exemplary embodiment described above accommodates three image displays 51, the present disclosure is not limited thereto. Projection image display device 100 may include one image display 51, and may store only one image display 51 and one heat receiving element in container 3. In this case, three colors of light of blue, green, and red are incident on image display 51 in a time-division manner.

As described above, the exemplary embodiments have been described to exemplify the techniques in the present disclosure. For that purpose, the accompanying drawings and the detailed description have been provided. Thus, the components described in the accompanying drawings and the detailed description include not only components essential for solving the problem but also components that are not essential for solving the problem and are for illustrating the above-described technique. For this reason, it should not be immediately construed that those non-essential components are essential only based on the fact that those non-essential components are illustrated in the accompanying drawings or described in the detailed description.

The above exemplary embodiments are provided to exemplify the techniques in the present disclosure, and thus enabling various changes, replacements, additions, omissions, and the like, within the scope of claims and equivalents thereof.

### Overview of Exemplary Embodiments

(1) A cooling device of the present disclosure includes: a container that is sealed and accommodates a first heating element; a first radiator disposed outside the container; a first air blower that blows wind to the first radiator; and a heat dissipator that is disposed outside the container to receive a flow of the wind from the first air blower and dissipates heat of the first heating element.

Dissipating heat of the first heating element outside the container and cooling the heat dissipator using the wind for cooling the first radiator, through which a refrigerant for cooling another member passes, enables achieving space saving of the cooling device for cooling the light shielding plate accommodated in the sealed container.

(2) Cooling device of (1) further includes a heat receiver that receives heat of a second heating element disposed in the container, a first flow path through which a refrigerant cooled by the first radiator flows to the heat receiver, and a second flow path through which the refrigerant raised in temperature by the heat receiver flows to the first radiator. This configuration allows heat of the first heating element to be dissipated by the heat dissipator, and heat of the second heating element to be received by the heat receiver cooled by the refrigerant. Only one of the two heating elements is cooled by the refrigerant, and thus the refrigerant can be prevented from excessively increasing in temperature and the first radiator can be prevented from enlarging. Additionally, the heat dissipator of the first heating element is cooled using a cooling wind to the first radiator that cools the refrigerant for cooling the second heating element. Thus, two coolers can be cooled by one air blower, so that space saving of the cooling device can be achieved.

(3) In the cooling device of (2), the heat dissipator is disposed to receive wind having passed through the first radiator.

(4) The cooling device of (2) or (3) includes a second air blower that is accommodated in the container and blows wind in the container.

(5) The cooling device of (4) includes a second radiator that is accommodated in the container and exchanges heat with air in the container. The second air blower blows wind to the second radiator, and the second flow path and the second radiator are connected in the middle of the second flow path. Through the second flow path, the refrigerant raised in temperature by the heat receiver flows to the second radiator, and the refrigerant further raised in temperature by the second radiator flows to the first radiator.

(6) In the cooling device according to any one of (2) to (5), the heat dissipator includes a metal fin connected to the first heating element.

(7) There is provided the cooling device according to any one of (2) to (5), a prism that is accommodated in a container and separate incident light by color separation, an image display disposed facing a first surface of the prism, as a second heating element, and a light shielding plate that shields light reflected from the image display, as a first heating element.

### INDUSTRIAL APPLICABILITY

The present disclosure is applicable to an image display device including a reflective image display element.

### REFERENCE MARKS IN THE DRAWINGS

1: cooling device
2: liquid-cooling system
3: container
3a: body
3b: lid
3ba: first upper surface
3bb: side surface
3bc: second upper surface
5: first radiator
7: first air blower
9: heat dissipator
11: light shielding plate
11a: photo detector
11b: heat-conducting plate
12, 13: pipe
15: heat receiver
15G: first heat receiving element
15B: second heat receiving element
15R: third heat receiving element
17: second radiator
19: second air blower
21, 23: pipe
51: image display
61: prism unit

1. A cooling device comprising:
a container that is sealed and accommodates a first heating element;
a first radiator disposed outside the container;
a first air blower that blows wind to the first radiator; and
a heat dissipator that is disposed outside the container to receive the wind from the first air blower and dissipates heat of the first heating element.

2. The cooling device according to claim 1, further comprising:
a heat receiver that is disposed in the container and receives heat of a second heating element disposed in the container;
a first flow path that is connected to the first radiator and the heat receiver, wherein a refrigerant cooled by the first radiator flows through the first flow path; and
a second flow path that is connected to the heat receiver and the first radiator, wherein the refrigerant raised in temperature by the heat receiver flows through the second flow.

3. The cooling device according to claim 2, wherein the heat dissipator is disposed to receive wind having passed through the first radiator.

4. The cooling device according to claim 2, further comprising a second air blower that is accommodated in the container and blows wind in the container.

5. The cooling device according to claim 4, further comprising a second radiator that is accommodated in the container and exchanges heat with air in the container,
wherein the second air blower blows wind to the second radiator, and
the second flow path includes:
a third flow path that is connected to the heat receiver and the second radiator, wherein the refrigerant raised in temperature by the heat receiver flows through the third flow path, and
a fourth flow path that is connected to the second radiator and the first radiator, wherein the refrigerant further raised in temperature by the second radiator flows through the fourth flow path.

6. The cooling device according to claim 2, wherein the heat dissipator includes a metal fin connected to the first heating element.

7. The cooling device according to claim 6, wherein the heat dissipator is connected to the first heating element via the container.

8. A projection image display device comprising:
the cooling device according to claim 2;
the first heating element;
the second heating element; and
a prism that is accommodated in the container to separate incident light into a plurality of colors of light and combine the plurality of colors of light,
wherein the second heating element includes an image display facing one surface of the prism, and
the first heating element includes a light shielding plate that shields light reflected from the image display.

9. The projection image display device according to claim 8, wherein the image display includes a digital mirror device.

10. The projection image display device according to claim 8, wherein the light shielding plate includes:
a photo detector that receives light reflected from the image display, and
a heat-conducting plate connected to the photo detector, and
the heat-conducting plate is connected to the heat dissipator via the container.
